(19) United States
(12) Patent Application Publication
(10) Pub. No.: US 2015/0348744 A1
(43) Pub. Date: Dec. 3, 2015

(54) MOVING APPARATUS AND CHARGED PARTICLE BEAM DRAWING SYSTEM

(71) Applicant: CANON KABUSHIKI KAISHA, Tokyo (JP)

(72) Inventors: Shinji Uchida, Utsunomiya-shi (JP); Nobushige Korenaga, Utsunomiya-shi (JP)

(21) Appl. No.: 14/725,557

(22) Filed: May 29, 2015

(30) Foreign Application Priority Data
Jun. 3, 2014 (JP) 2014-115280

(51) Int. Cl. H01J 37/20; G03F 7/20; H01J 37/317

(52) U.S. Cl. CPC H01J 37/20; H01J 37/3174; G03F 7/2059; H01J 2237/202

(57) ABSTRACT

A moving apparatus includes a moving member movable in a first direction, a drive unit that drives the moving member, and a magnetic field shielding unit made of a magnetic material to shield at least part of a magnetic field emanating from the drive unit. The drive unit includes a stator and a movable element connected to the moving member. The magnetic field shielding unit includes a first plate connected to the moving member and disposed between the moving member and the movable element, two side plates connected to the first plate and having end portions extending in the first direction, and a second plate connected to the stator and extending in the first direction to surround the movable element and at least part of the stator at plural positions in accordance with movement of the moving member in the first direction together with the first plate and side plates.

### BACKGROUND OF THE INVENTION

1. Field of the Invention

The present invention relates to a moving apparatus and a charged particle beam drawing system including a moving apparatus.

2. Description of the Related Art

Electron beam drawing systems serving as one of photomask generating tools have been developed. Electron beam drawing systems emit an electron beam to a substrate and draws a pattern on the substrate. In addition, in recent years, to manufacture semiconductor devices, multi-beam electron beam drawing systems that emit a plurality of electron beams to a substrate at the same time have been developed.

To manufacture semiconductor devices, the processing ability (the throughput) that is higher than that of existing electron beam drawing systems is required. Accordingly, a moving apparatus needs to move a substrate at high speed.

In general, existing optical exposure systems, such as a stepper or a scanner, lift a moving member using an air guide mechanism and guides movement of the moving member. At that time, the electron beam drawing systems need to emit an electron beam to the substrate in the vacuum environment. Accordingly, to ensure the reliability, it is desirable that the substrate be moved without using an air guide mechanism.

Japanese Patent Laid-Open No. 2011-3782 describes an exposure system (an exposure system using EUV light) that guides movement of a moving member without using an air guide. The exposure system described in Japanese Patent Laid-Open No. 2011-3782 includes a coarse moving stage and a fine moving stage. The exposure system lifts the fine moving stage using a voice coil motor and guides movement of a moving member.

The voice coil motor of the exposure system described in Japanese Patent Laid-Open No. 2011-3782 is not covered by a magnetic shield. Accordingly, if the configuration described in Japanese Patent Laid-Open No. 2011-3782 is applied to the moving apparatus of an electron beam drawing system, a magnetic field emanating from the voice coil motor may adversely affect the beam pointing precision (the drawing precision).

In addition, if the stator and the movable element of the voice coil motor is separately covered by a magnetic shield to completely block the magnetic field emanating from each of elements, the weight of a unit that moves together with the moving member increases. Furthermore, to prevent interference between movements of the stator and the movable element, the variability in layout of the stator and the movable element is significantly restricted.

### SUMMARY OF THE INVENTION

The present invention provides a moving apparatus. The moving apparatus includes a moving member configured to be movable in a first direction, a drive unit configured to drive the moving member, and a magnetic field shielding unit made of a magnetic material, where the magnetic field shielding unit shields at least part of a magnetic field emanating from the drive unit. The drive unit includes a stator and a movable element connected to the moving member. The magnetic field shielding unit includes a first plate connected to the moving member and disposed between the moving member and the movable element, a pair of side plates connected to the first plate on either side of the movable element and having end portions extending in the first direction, and a second plate connected to the stator. The second plate is disposed so as to extend in the first direction and surround the movable element and at least part of the stator at a plurality of positions in accordance with movement of the moving member in the first direction together with the first plate and the pair of side plates.

Further features of the present invention will become apparent from the following description of exemplary embodiments with reference to the attached drawings.

### BRIEF DESCRIPTION OF THE DRAWINGS

FIG. 1 is a schematic illustration of the configuration of an electron beam drawing system.

FIG. 2A is a top view of moving units XMV and YMV.

FIG. 2B is a view on arrow IIB-IIB of FIG. 2A.

FIG. 3 is a front view of the moving unit YMV and its vicinity.

FIG. 4 is a view on arrow IV-IV of FIG. 3.

FIG. 5 illustrates the operation performed by the moving units XMV and YMV in the drawing sequence.

FIG. 6 illustrates a modification of a magnetic shield unit.

### DESCRIPTION OF THE EMBODIMENTS

### Configuration of Electron Beam Drawing System

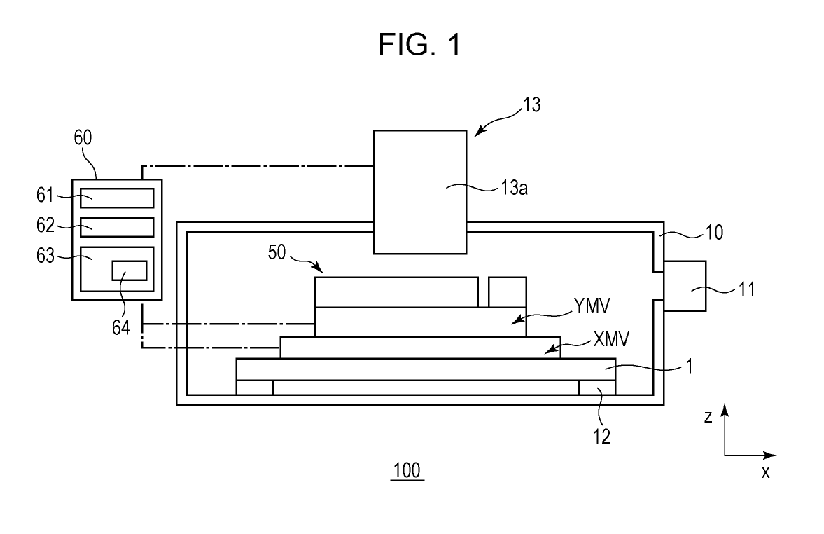

FIG. 1 is a schematic illustration of the configuration of an electron beam drawing system (a charged particle beam drawing system) 100 according to the present exemplary embodiment. The electron beam drawing system 100 is used in a lithography process which is one of a semiconductor device manufacturing processes. In FIG. 1, the vertical direction is defined as a Z-axis direction (a second direction). Two directions that are perpendicular to each other in the horizontal plane are defined as an X-axis direction (a third direction) and a Y-axis direction (a first direction).

The electron beam drawing system 100 includes a chamber 10, an electron beam emitting unit 13, and a stage apparatus 50.

The chamber 10 serves as a partition wall that separates the space around the stage apparatus 50 from an external space. The chamber 10 has a vacuum pump 11 connected thereto. The vacuum pump 11 exhausts air in the chamber 10. An example of the vacuum pump 11 is a cryo pump or a turbo molecular pump. The chamber 10 and the vacuum pump 11 form a vacuum environment around the stage apparatus 50.

The electron beam emitting unit 13 generates an electron beam and emits a plurality of electron beams to an area of a wafer (a substrate). The electron beam emitting unit 13 includes an electron gun (not illustrated) that generates the electron beam, an aperture array (not illustrated) that separates the electron beam generated by the electron gun into a plurality of electron beams, a control element array (not illustrated) that turns on and off each of the plurality of electron beams, and a deflection array (not illustrated) that deflects each of the plurality of electron beams. These elements are included in a chassis 13a. Note that the configuration of the electron beam emitting unit 13 is not limited thereto. Any configuration that forms a pattern on a wafer using a plurality of electron beams can be employed. For example, a reflective control element array can be used as the control element array.

The stage apparatus (moving apparatus) 50 positions the wafer in place (at a predetermined location). The stage apparatus 50 includes a base 1 supported by the bottom surface (or the floor) of the chamber 10 via mounts 12, a moving unit XMV that is movable relative to the base 1 in the X-axis direction, and a moving unit YMV that is movable relative to the moving unit XMV in the Y-axis direction. The mount 12 includes an air spring so as to reduce vibrations transferred from the bottom surface (or the floor) of the chamber 10 to the base 1. The mount 12 is provided in each of four corners of the bottom surface of the base 1.

The electron beam drawing system 100 includes a control unit 60. The control unit 60 includes a plurality of circuit boards each having, for example, a central processing unit (CPU) and a memory. The circuit boards are contained in a control rack. The control unit 60 further includes a main control unit 61 that controls the sequence of operations of the electron beam drawing system and a unit control unit that controls each of units that constitute the electron beam drawing system 100. In FIG. 1, as the unit control units, an emission control unit 62 that controls the electron beam emitting unit 13 and a stage control unit 63 that controls the stage apparatus 50 are illustrated. The stage control unit 63 includes a driver (an amplifier), a CPU, and a memory. The stage control unit 63 controls the movements of the moving unit XMV and the moving unit YMV. The stage control unit 63 can communicate with the main control unit 61 and controls the moving unit XMV and the moving unit YMV using information received from the main control unit 61.

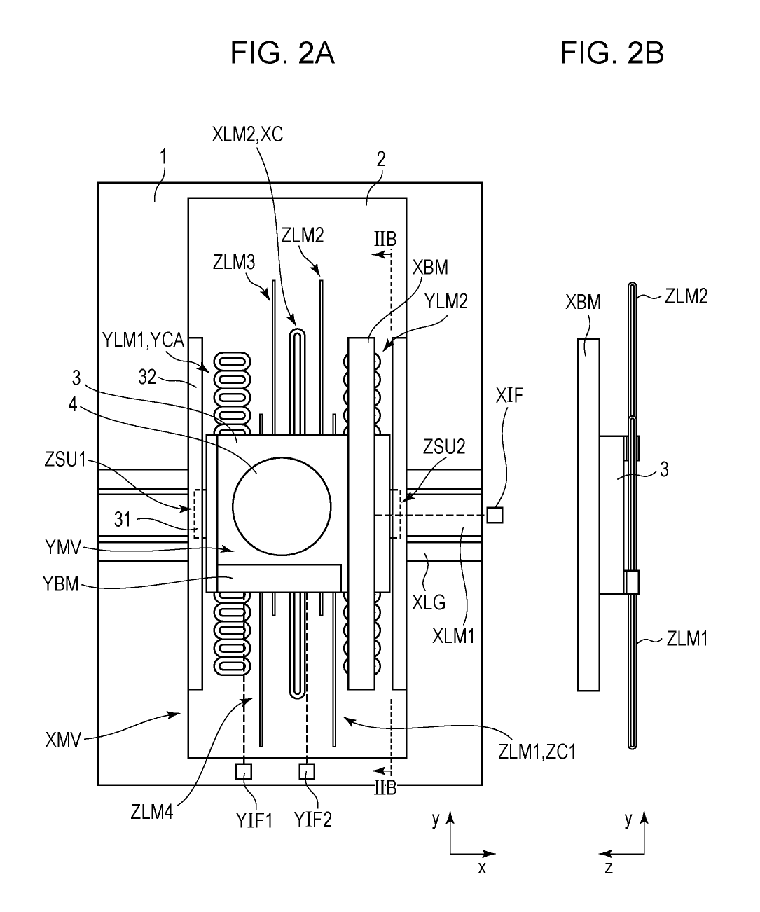

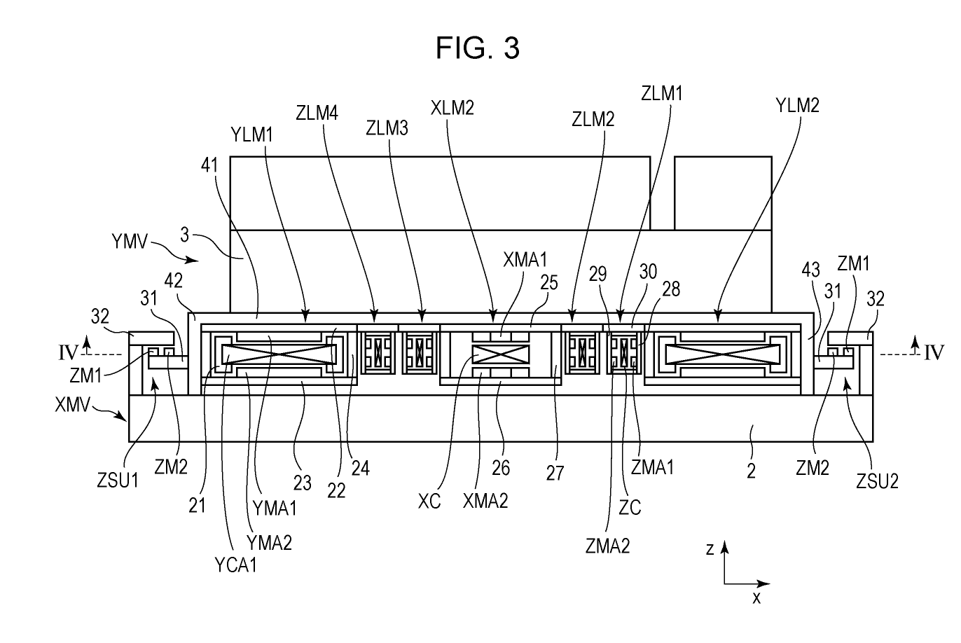

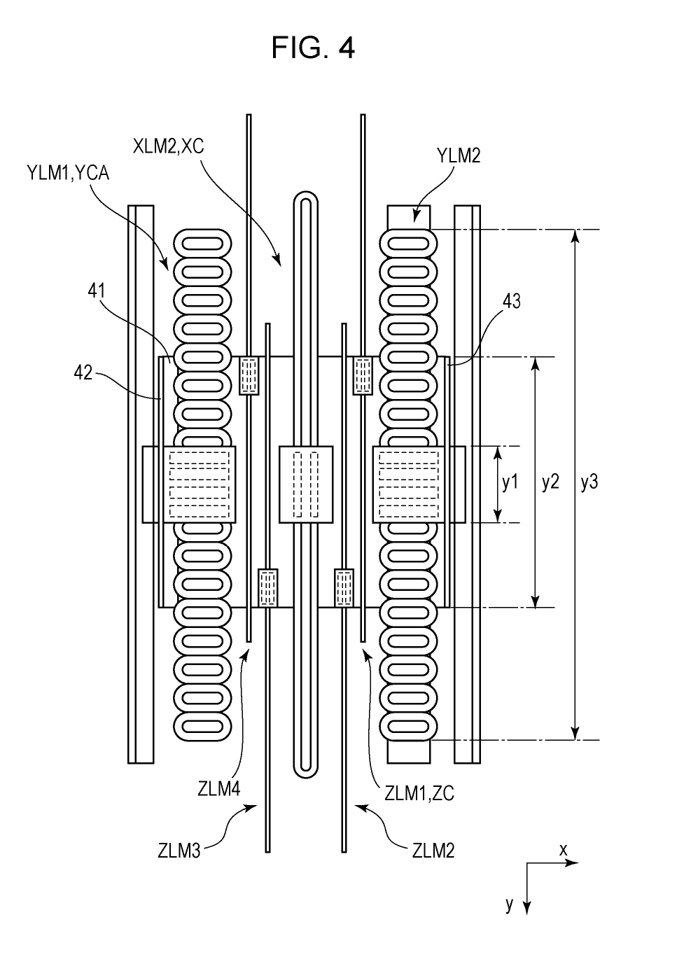

FIG. 2A is a top view of the moving unit XMV and the moving unit YMV. FIG. 2B is a view on arrow IIB-IIB of FIG. 2A (some of the configuration is not illustrated). FIG. 3 is a front view of the moving unit YMV and its vicinity. FIG. 4 is a view on arrow IV-IV of FIG. 3 (some of the configuration is not illustrated). The configurations of the units that constitute the stage apparatus 50 are described below with reference to FIGS. 2A and 2B and FIGS. 3 and 4.

### Configuration of Moving Unit XMV

The configuration of the moving unit XMV is described below with reference to FIG. 2A. The moving unit XMV includes a top panel 2, the movable element (not illustrated) of a linear motor XLM1 disposed on the lower surface of the top panel 2, the stators of a linear motors YLM1 and YLM2 disposed on the upper surface of the top plate 2, the stators of linear motors ZLM1, ZLM2, ZLM3, and ZLM4, and the stator of a linear motor XLM2. The stator of the linear motor XLM1 is disposed on the base 1 so as to extend in the X-axis direction. The moving unit XMV is movable in the X-axis direction by a thrust force generated by the linear motor XLM1. The moving unit XMV is supported on the base 1 by a linear guide XLG. The linear guide XLG guides movement of the moving unit XMV in the X-axis direction. The linear guide XLG is also referred to as a “rolling guide” or a “rolling bearing”. The linear guide XLG includes rolling elements, such as balls (steel balls) or rollers.

The position of the moving unit XMV in the X-axis direction is measured by a position sensor (not illustrated). The stage control unit 63 drives the linear motor XLM1 on the basis of the output of the position sensor and information received from the main control unit 61. Thus, the stage control unit 63 controls the position of the moving unit XMV. For example, a linear encoder or an interferometer can be used as the position sensor.

### Configuration of Moving Unit YMV

The configuration of the moving unit YMV is described below with reference to FIG. 2A and FIG. 3. The moving unit YMV includes a top panel 3 (a moving member) having the wafer placed thereon. A wafer chuck 4 having a wafer holding surface is attached to the top panel 3. The top panel 3 is formed from a silicon steel plate or a ceramic plate. In addition, the moving unit YMV includes the movable elements of the linear motors YLM1 and YLM2, the movable elements of the linear motors ZLM1, ZLM2, ZLM3, and ZLM4, and the movable element of the linear motor XLM2, which are sequentially arranged from the end of the moving unit YMV in the X-axis direction. The configurations of such linear motors are described in more detail below.

The moving unit YMV is movable in the Y-axis direction by the thrust force generated by the linear motors YLM1 and YLM2. In addition, the moving unit YMV is movable in the X-axis direction by the thrust force generated by the linear motor XLM2. Furthermore, the moving unit YMV is movable in the Z-axis direction by the thrust force generated by the linear motors ZLM1, ZLM2, ZLM3, and ZLM4. Still furthermore, the moving unit YMV is movable in a θz direction (a rotation direction about the Z-axis) in accordance with a difference between the thrust forces generated by the linear motors YLM1 and YLM2 and is movable in a θx direction (a rotation direction about the X-axis) and a θy direction (a rotation direction about the Y-axis) in accordance with a difference among the thrust forces generated by the linear motors ZLM1, ZLM2, ZLM3, and ZLM4.

The position of the moving unit YMV is measured by an interferometer. Mirrors XBM and YBM are attached to the upper surface of the top panel 3 in order to measure the position of the moving unit YMV. The mirror XBM has a reflecting surface that extends along a YZ plane. The mirror XBM reflects a measurement light ray emitted from an interferometer XIF to lead the measurement light ray to the interferometer XIF. The mirror YBM has a reflecting surface that extends along an XZ plane. The mirror YBM reflects measurement light rays emitted from interferometers YIF1 and YIF2 to lead the measurement light rays to the interferometers YIF1 and YIF2, respectively. The interferometers XIF, YIF1, and YIF2 measure the positions of the moving unit YMV in the X-axis direction, the Y-axis direction, and the θz direction on the basis of the measurement light. In addition, the mirror XBM has a reflecting surface that extends along an XY plane. The positions of the moving unit YMV in the Z-axis direction, the θx direction, and the θy direction are measured by using an interferometer (not illustrated). The stage control unit 63 drives each of the linear motors on the basis of the information received from the main control unit 61 and measures the position of the moving unit YMV. Thus, the stage control unit 63 controls the position of the moving unit YMV.

The moving unit YMV further includes an upper plate 41 and side plates 42 and 43, which are part of a magnetic shield unit (a magnetic field shielding unit). That is, the magnetic shield unit includes the upper plate 41 and the side plates 42 and 43, and the top panel 2 that block at least part of the magnetic field emanating from the linear motors YLM1 and YLM2, the linear motors ZLM1, ZLM2, ZLM3, and ZLM4, and the linear motors XLM1 and XLM2. The configuration of the magnetic shield unit is described in more detail below.

The moving unit YMV further includes magnetic members 32, which are part of a lifting support units ZSU1 and ZSU2 that lift and support the moving unit YMV and permanent magnets ZM1 and ZM2 attached to the magnetic members 32. The configurations of the lifting support units ZSU1 and ZSU2 are described in more detail below.

### Configuration of Linear Motors YLM1 and YLM2

The Configuration of the linear motors (drive units) YLM1 and YLM2 are described with reference to FIGS. 2A, 3, and 4. The linear motors YLM1 and YLM2 are disposed so as to be separated from each other in the X-axis direction. Hereinafter, only the configuration of the linear motor YLM1 is described. Since the configuration of the linear motor YLM2 is similar to that of the linear motor YLM1, description of the configuration of the linear motor YLM2 is not repeated.

The linear motor YLM1 includes a movable element and a stator. The movable element includes magnet arrays YMA1 and YMA2 (a movable element) connected to the bottom surface of the top panel 3. The stator includes a coil array YCA (a stator) disposed on the upper surface of the top panel 2.

The magnet arrays YMA1 and YMA2 are supported by a supporting member (a yoke 22, a yoke 23, and connecting members 24) so as to face each other with a predetermined gap therebetween. Each of the magnet arrays YMA1 and YMA2 includes a plurality of the permanent magnets (magnets) arranged in the Y-axis direction. The permanent magnets that constitute each of the magnet arrays YMA1 and YMA2 include the permanent magnets each having an N (north) pole on the lower surface and the permanent magnets each having an S (south) pole on the lower surface, which are alternately arranged. According to the present exemplary embodiment, each of the magnet arrays YMA1 and YMA2 includes four permanent magnets. However, the number of permanent magnets is not limited thereto. In addition, the permanent magnets that constitute the magnet array YMA1 and the permanent magnets that constitute the magnet array YMA2 are configured so that opposite poles face each other.

The supporting member includes the yoke 22 fixed to the upper surface of the magnet array YMA1, the yoke 23 fixed to the lower surface of the magnet array YMA2, and the pair of connecting members 24 that connect both ends of the yoke 22 in the X-axis direction to both ends of the yoke 23 in the X-axis direction. Each of the yokes 22 and 23 is formed from a soft iron plate. The yokes 22 and 23 increase the magnetic flux between the magnet arrays YMA1 and YMA2.

The coil array YCA is disposed so that the length direction thereof is the Y-axis direction. The coil array YCA includes a plurality of coils arranged in the Y-axis direction. Each of the coils includes two linear conductive portions extending in the X-axis direction. The coils are arranged in the Y-axis direction at intervals corresponding to the arrangement of the permanent magnets that constitute the magnet array YMA1. The coils are supported by a supporting member 21 at both ends thereof in the X-axis direction. The supporting member 21 is disposed so that the length direction thereof is the Y-axis direction. Both ends of the supporting member 21 in the Y-axis direction are fixed to the top panel 2.

Through such a configuration, a thrust force is applied to the moving unit YMV (the top panel 3) in the Y-axis direction. The thrust force is generated by an interaction between the magnetic flux emanating from the magnet arrays YMA1 and YMA2 and an electric current flowing in the conductive portions of the coils.

The linear motors YLM1 and YLM2 are controlled by the stage control unit 63. According to the present exemplary embodiment, the control is performed by using a multi-phase excitation drive mode (two phases in the present exemplary embodiment). The driver supplies an electric current to each of the coils of the multi-phases in accordance with the position of the moving unit YMV in the Y-axis direction. In addition, the stage control unit 63 includes a switching circuit 64 (a switching unit) that switches the excitation among the plurality of coils in accordance with the position of the moving unit YMV in the Y-axis direction. The switching circuit 64 supplies an electric current to only coils that face the magnet arrays YMA1 or YMA2 or the top panel 3. In this manner, a magnetic field is not generated by the coil that does not generate the thrust force and the coil that is not covered by the top panel 3.

In addition, by making the thrust force generated by the linear motor YLM1 differ from that generated by the linear motor YLM2, the moving unit YMV can be driven in the Oz direction.

The length of a coil array YCA1 in the Y-axis direction is greater than or equal to twice the length of the wafer holding surface in the Y-axis direction (in the present exemplary embodiment, a 300-mm wafer is used). For example, the length of the coil array YCA1 is greater than or equal to 600 mm and less than 1500 mm. In addition, to reduce the size of the stage apparatus 50 and the movement stroke for, for example, calibration and transfer, it is desirable that the length of the coil array YCA1 be greater than or equal to 700 mm and less than 1200 mm.

### Configuration of Linear Motors ZLM1, ZLM2, ZLM3, and ZLM4

The Configurations of the linear motors (drive units) ZLM1, ZLM2, ZLM3, and ZLM4 are described with reference to FIGS. 2A and 2B and FIGS. 3 and 4. The linear motors (drive units) ZLM1, ZLM2, ZLM3, and ZLM4 are arranged in the X-axis direction so as to be separated from each other. Hereinafter, only the configuration of the linear motor ZLM1 is described. Since the configurations of the linear motors ZLM2, ZLM3, and ZLM4 are similar to that of the linear motor ZLM1, description of the configurations of the linear motors ZLM2, ZLM3, and ZLM4 are not repeated.

The linear motor ZLM1 includes a movable element and a stator. The movable element includes magnet arrays (the movable elements) ZMA1 and ZMA2 disposed on the bottom surface of the top panel 3. The stator includes a coil array (a stator) ZC disposed on the upper surface of the top panel 2.

The magnet arrays ZMA1 and ZMA2 are supported by a supporting member (a yoke 28, a yoke 29, and connecting members 30) so as to face each other with a predetermined gap therebetween. Each of the magnet arrays ZMA1 and ZMA2 includes a plurality of the permanent magnets (magnets) arranged in the Z-axis direction. The permanent magnets that constitute each of the magnet arrays ZMA1 and ZMA2 include the permanent magnets each having an N (north) pole on the right surface (a surface on the +X side) and the permanent magnets each having an S (south) pole on the left surface (a surface on the −X side). According to the present exemplary embodiment, each of the magnet arrays includes two permanent magnets. In addition, the permanent magnets that constitute the magnet array ZMA1 and the permanent magnets that constitute the magnet array ZMA2 are configured so that opposite poles face each other.

The supporting member includes the yoke 28 fixed to the right side surface of the magnet array ZMA1, the yoke 29 fixed to the left side surface of the magnet array ZMA2, and the pair of connecting members 30 that connect both ends of the yoke 28 in the Z-axis direction to both ends of the yoke 29 in the Z-axis direction. Each of the yokes 28 and 29 is formed from a soft iron plate. The yokes 28 and 29 increase the magnetic flux between the magnet arrays ZMA1 and ZMA2.

The coil ZC is disposed so that the length direction thereof is the Y-axis direction. The coil ZC is supported by a supporting member. The supporting member is fixed to the moving unit XMV at both ends of the coil ZC in the Y-axis direction. The coil ZC includes two linear conductive portions extending in the Y-axis direction. Each of the two conductive portions is disposed so as to face one of the two permanent magnets that constitute the magnet array ZMA1 (ZMA2) and that are arranged in the Z-axis direction.

In such a configuration, by passing an electric current through the conductive portion of the coil ZC in which the magnetic fluxes emanating from the magnet arrays ZMA1 and ZMA2 are interlinked, a thrust force is applied to the moving unit YMV (the top panel 3) in the Z-axis direction. The movement stroke of the top panel 3 in the Z-axis direction caused by the linear motors ZLM1, ZLM2, ZLM3, and ZLM4 is less than the movement stroke of the top panel 3 in the Y-axis direction caused by the linear motors YLM1 and YLM2.

### Configuration of Linear Motor XLM2

The Configuration of the linear motor (a drive unit) XLM2 is described with reference to FIGS. 2A, 3, and 4.

The linear motor XLM2 includes a movable element and a stator. The movable element includes magnet arrays XMA1 and XMA2 (a movable element) disposed on the bottom surface of the top panel 3. The stator includes a coil XC (a stator) disposed on the upper surface of the top panel 2.

The magnet arrays XMA1 and XMA2 are supported by a supporting member (a yoke 25, a yoke 26, and connecting members 27) so as to face each other with a predetermined gap therebetween. Each of the magnet arrays XMA1 and XMA2 includes a plurality of the permanent magnets (magnets) arranged in the X-axis direction. The permanent magnets that constitute each of the magnet arrays XMA1 and XMA2 include the permanent magnets each having an N (north) pole on the upper surface and the permanent magnets each having an S (south) pole on the lower surface. According to the present exemplary embodiment, each of the magnet arrays includes two permanent magnets. In addition, the permanent magnets that constitute the magnet array XMA1 and the permanent magnets that constitute the magnet array XMA2 are configured so that opposite poles face each other.

The supporting member includes the yoke 25 fixed to the upper surface of the magnet array XMA1, the yoke 26 fixed to the lower surface of the magnet array XMA2, and the pair of connecting members 27 that connect both ends of the yoke 25 in the X-axis direction to both ends of the yoke 26 in the X-axis direction. Each of the yokes 25 and 26 is formed from a soft iron plate. The yokes 25 and 26 increase the magnetic flux between the magnet arrays ZMA1 and ZMA2.

The coil XC is disposed so that the length direction thereof is the Y-axis direction. The coil XC is supported by a supporting member. The supporting member is fixed to the moving unit XMV at both ends of the coil XC in the Y-axis direction. The coil XC includes two linear conductive portions extending in the Y-axis direction. Each of the two conductive portions is disposed so as to face one of the two permanent magnets that constitute the magnet array XMA1 (XMA2) and that are arranged in the X-axis direction.

In such a configuration, by passing an electric current through the conductive portion of the coil XC in which the magnetic fluxes generated by the magnet arrays XMA1 and XMA2 are interlinked, a thrust force is applied to the moving unit YMV (the top panel 3) in the X-axis direction. The movement stroke of the top panel 3 in the X-axis direction caused by the linear motor XLM2 is less than the movement stroke of the top panel 3 in the Y-axis direction caused by the linear motors YLM1 and YLM2.

### Configuration of Magnetic Shield Unit

The magnetic shield unit includes the upper plate (a first plate) 41 connected to the top panel 3 and disposed between the top panel 3 and a moving element group, a pair consisting of the side plates 42 and 43 that are connected to the upper plate 41 on either side of the moving element group and that have end portions extending along the Y-axis direction, and the top panel (a second plate) 2. Each of the upper plate 41 and the top panel 3 has a plane that extends along the XY plane and a plane that extends along the YZ plane. The upper plate 41, the side plates 42 and 43, and the top panel 2 are made of a magnetic material. An example of the magnetic material is a high-permeability material, such as iron or nickel.

The top panel 2 is disposed under the stator group (the stator) of the linear motors YLM1, YLM2, ZLM1, ZLM2, ZLM3, ZLM4, and XLM2 in the moving range of the moving unit YMV (or the movable element) in the Y-axis direction. That is, the top panel 2 is disposed so as to surround the moving element group and part of the stator group (the moving element group and at least part of the stator group) together with the upper plate 41 and the side plates 42 and 43 at a plurality of positions in accordance with the movement of the top panel 3 in the Y-axis direction. Example of the plurality of positions are the positions of both ends of the moving range (the movement stroke) of the moving member. In addition, let y1 be the length of the movable element of each of the linear motors YLM1 and YLM2, let y2 be the length of the upper plate 41 of the magnetic shield unit, and let y3 be the length of the stator of each of the linear motors YLM1 and YLM2. Then, the relationship y1<y2<y3 is satisfied.

In addition, the top panel 2 is disposed so as to face the end portions of the side plates 42 and 43 with a gap therebetween at a plurality of positions in accordance with the movement of the top panel 3 in the Y-axis direction. The lengths of the upper plate 41 in the X-axis direction and the Y-axis direction are greater than the size of a region in which the moving element group is disposed.

### Configuration of Lifting Support Units ZSU1 and ZSU2

The configuration of lifting support units ZSU1 and ZSU2 are described below with reference to FIGS. 2A and 3. The lifting support units ZSU1 and ZSU2 are disposed so as to be separated from each other in the X-axis direction. Hereinafter, only the configuration of the lifting support unit ZSU1 is described. Since the configuration of the lifting support unit ZSU2 is the same as that of the lifting support unit ZSU1, description of the lifting support unit ZSU2 is not repeated.

The lifting support unit ZSU1 includes a magnetic member 31 and the permanent magnet ZM1 and ZM2 attached to the side plate 42 of the magnetic shield unit and the magnetic member 32 supported by a supporting member on the top panel 2.

The magnetic member 32 extends in the Y-axis direction across the movement stroke of the moving unit YMV in the Y-axis direction. The magnetic member 32 has a planar portion that extends along the XY plane. The permanent magnet ZM1 has an N pole on the upper surface. In contrast, the permanent magnet ZM2 has an S pole on the upper surface. The magnetic poles face the planar portion with a very small gap therebetween. Thus, a magnetic attractive force in accordance with a magnetic gap can be generated between the planar portion and the magnetic poles.

According to the lifting support units ZSU1 and ZSU2 of the present exemplary embodiment, a lift force can be applied to the moving unit YMV using the magnetic attractive force that varies with the square of the magnetic gap. Accordingly, the heat value of the linear motors ZLM1, ZLM2, ZLM3, and ZLM4 can be reduced from the heat value generated when only the linear motors ZLM1, ZLM2, ZLM3, and ZLM4 apply the lift force to the moving unit YMV.

Note that the number of the permanent magnets that constitute each of the lifting support units ZSU1 and ZSU2 and the layout of the magnetic poles are not limited to those of the configuration of the present exemplary embodiment.

In general, existing lithography systems have a configuration in which a moving unit that moves through a long stroke is lifted by a hydrostatic bearing. In such a configuration like the configuration of electron beam drawing systems, when exposure is performed in a vacuum atmosphere and if gas leaks to the vicinity of a stage apparatus, there is a risk of loss of vacuum. According to the present exemplary embodiment, since the lifting support units ZSU1 and ZSU2 apply the lift force to the moving units XMV and YMV using the magnetic attractive force, the reliability of the system can be increased.

### Operations Performed by Moving Units XMV and YMV in Drawing Sequence

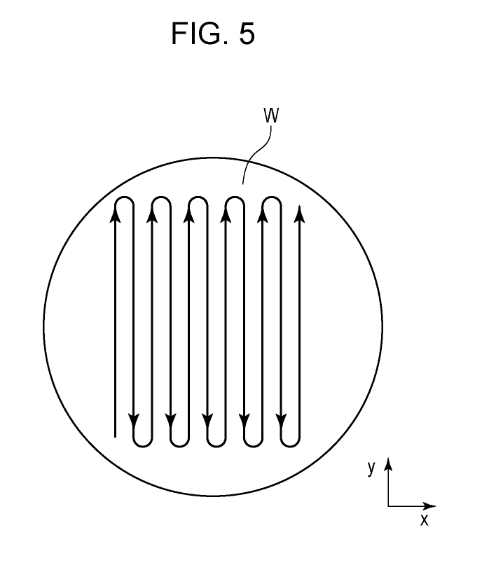

The operations performed by the moving units XMV and YMV in a drawing sequence are described below with reference to FIG. 5. The drawing sequence described below is performed by the control unit 60.

The drawing sequence is applied to a wafer W that is carried into the electron beam drawing system 100 and is placed on the holding surface of the wafer chuck 4.

The stage control unit 63 emits a plurality of electron beams onto the wafer W and scans the moving unit YMV in the Y-axis direction. After one scan is completed, the stage control unit 63 moves the moving unit XMV and the moving unit YMV in the X-axis direction. Thereafter, the stage control unit 63 emits a plurality of electron beams onto the wafer W again and scans the moving unit YMV in the Y-axis direction (in a direction opposite to the direction for the above-described scan). By alternately performing an operation to scan over the wafer W (the top panel 2) in the Y-axis direction and an operation to scan in the X-axis direction (by repeating the operations), a pattern can be formed on the entire surface of the wafer W.

As described above, the magnetic shield unit according to the present exemplary embodiment includes the upper plate 41 connected to the moving member, a pair consisting of the side plates 42 and 43 connected to the upper plate 41, and the top panel 3 connected to the stator. In addition, the top panel 3 surrounds the movable element and part of the stator at a plurality of positions in accordance with the movement of the moving member in the Y-axis direction together with the side plates 42 and 43. By employing such a configuration, the weight of the moving unit can be reduced from that in a configuration in which each of the stator and the movable element is independently covered by a magnetic shield. In addition, the flexibility in the layout of the movable element and the stator can be increased.

Note that the term “connection” is not limited to a state in which two objects are directly connected to each other (two objects are in contact with each other). That is, as used herein, the term “connection” also refers to a state in which two objects are indirectly connected to each other with another member disposed therebetween.

The magnetic shield unit according to the present exemplary embodiment surrounds the movable elements of the linear motors YLM1, YLM2, ZLM1, ZLM2, ZLM3, ZLM4, and XLM2 in a predetermined plane that is perpendicular to the Y-axis direction. However, the magnetic shield unit may surround the movable element of any of the linear motors. For example, only the linear motors XLM2, ZLM1, ZLM2, ZLM3, and ZLM4 may be disposed between the top panel 2 and the top panel 3, and the magnetic shield unit may surround the linear motors. By surrounding a plurality of linear motors having different driving directions using a single magnetic shield unit, the weight of the moving unit can be reduced more and, thus, the flexibility in the layout of the movable element and the stator can be increased more.

Since the lower end portions of the pair of side plates of the magnetic shield unit according to the present exemplary embodiment face the upper surface of the lower plate, leakage of the magnetic field that passes between the side plate and the lower plate can be reduced.

While the present exemplary embodiment has been described with reference to the magnetic shield unit having the upper plate and the side plates integrated with one another, separate upper plate and side plate may be connected by screwing or bonding.

While the present exemplary embodiment has been described with reference to the lower plate of the magnetic shield unit serving as the top panel 2, the lower plate (the second plate) of the magnetic shield unit may be additionally provided on the upper surface of the top panel 2. In such a case, the top panel 2 can be formed of a material other than a magnetic material. Accordingly, the flexibility in terms of the rigidity, the weight, and workability can be increased.

### Modification

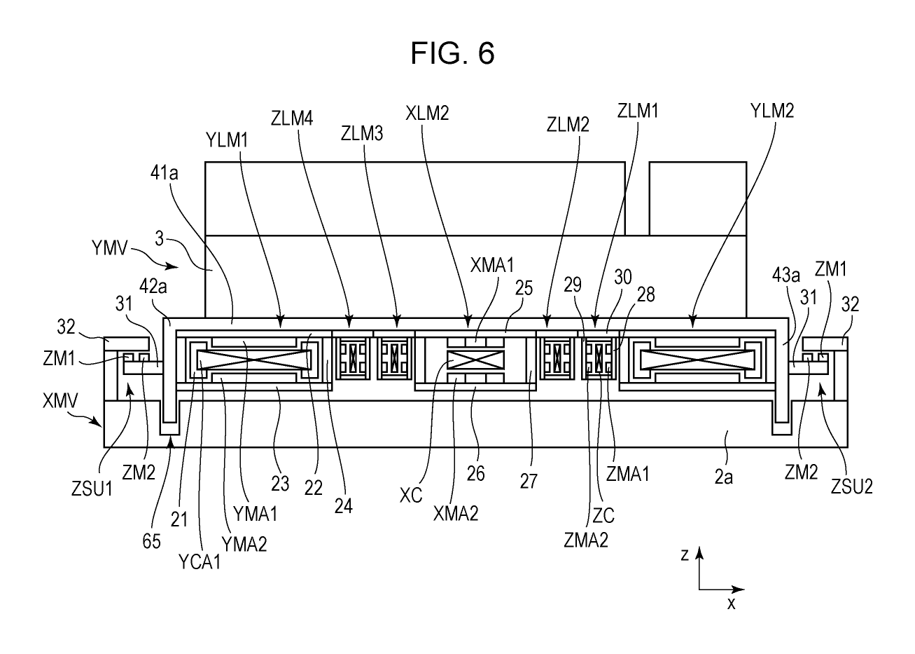

A modifications of the magnetic shield unit is described below with reference to FIG. 6. According to the modification, the configuration of the side plate and the lower plate of a magnetic shield unit differs from that of the above-described exemplary embodiment.

According to the modification, a magnetic shield unit includes an upper plate 41a disposed on the bottom surface of the top panel 3, a pair consisting of side plates 42a and 43a connected to the magnetic shield unit 41a, and a top plate 2a. The upper plate 41a, the side plates 42a and 43a, and the top plate 2a correspond to the upper plate 41, the side plates 42 and 43, and the top plate 2 of the above-described exemplary embodiment, respectively. The elements and configurations that are not described below are the same as those of the exemplary embodiment.

The top plate 2a has grooves 65 at positions that face the side plates 42a and 43a. The lower portions of the side plates 42a and 43a are inserted into the grooves 65.

Manufacturing Method of Product using Electron Beam Drawing System

A manufacturing method of a product (e.g., a semiconductor integrated circuit element, a liquid crystal display device, a CD-rewritable (CD-RW), a photomask, or a microelectromechanical system (MEMS)) using the electron beam drawing system includes a step of forming a pattern latent image on a substrate having a resist applied thereonto using the charged particle beam drawing system of the above-described exemplary embodiment and a step of developing the substrate having the pattern latent image thereon. In addition, the manufacturing method may include another working step, such as an oxidation step, a film forming step, a vapor deposition step, a doping step, a flattening step, a resist removing step, a dicing step, a bonding step, or a packaging step.

While the present exemplary embodiment has been described with reference to an electron beam drawing system, an ion beam may be used instead of an electron beam. That is, the present exemplary embodiment is applicable to a charged particle beam drawing system that draws a pattern using a charged particle beam. In addition, the present exemplary embodiment is not limited to an electron beam drawing system of a multi-beam type. The present exemplary embodiment is applicable to a drawing system that uses a single beam.

The moving apparatus according to the present exemplary embodiment is applicable to any system that performs a predetermined process by moving a substrate and that is required to reduce a magnetic field variation occurring in the vicinity of the substrate in addition to a system that manufactures a semiconductor device. Examples of the substrate can include a wafer and a glass substrate. The material is not limited to any particular material, and the thickness of the substrate is not limited to any particular value.

According to the present exemplary embodiment, a moving apparatus including a drive unit having a stator and a movable element and capable of reducing the magnetic field leaked from the drive unit into the vicinity can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-115280 filed Jun. 3, 2014, which is hereby incorporated by reference herein in its entirety.

What is claimed is:

1. A moving apparatus comprising:
a moving member configured to be movable in a first direction;
a drive unit configured to drive the moving member; and
a magnetic field shielding unit made of a magnetic material, the magnetic field shielding unit shielding at least part of a magnetic field emanating from the drive unit,
wherein the drive unit includes a stator and a movable element connected to the moving member,
wherein the magnetic field shielding unit includes
a first plate connected to the moving member and disposed between the moving member and the movable element, a pair of side plates connected to the first plate on either side of the movable element and having end portions extending in the first direction, and
a second plate connected to the stator, and
wherein the second plate is disposed so as to extend in the first direction and surround the movable element and at least part of the stator at a plurality of positions in accordance with movement of the moving member in the first direction together with the first plate and the pair of side plates.

2. The moving apparatus according to claim 1, wherein the stator includes a coil, and the movable element includes a magnet.

3. The moving apparatus according to claim 1, wherein the second plate is disposed so as to face the end portions with a gap therebetween at a plurality of positions in accordance with movement of the moving member in the first direction.

4. The moving apparatus according to claim 1, wherein the drive unit drives the moving member in a second direction different from the first direction, and
wherein a movement stroke of the moving member driven by the drive unit in the second direction is less than a movement stroke of the moving member in the first direction.

5. The moving apparatus according to claim 2, wherein the coil is disposed so that a length direction of the coil is the first direction.

6. The moving apparatus according to claim 2,
wherein the drive unit drives the moving member in the first direction, and
the coil includes a plurality of coils arranged in the first direction, and
wherein the moving apparatus further comprising:
a switching unit configured to switch excitation among the plurality of coils in accordance with a position of the moving member in the first direction.

7. The moving apparatus according to claim 1,
wherein the drive unit includes a drive unit that drives the moving member in a second direction different from the first direction and a drive unit that drives the moving member in a third direction different from the first and second directions.

8. A charged particle beam drawing system comprising:
the moving apparatus according to claim 1,
wherein the charged particle beam drawing system alternately performs an operation to move the moving member in the first direction and an operation to move the moving member in the second direction using the moving apparatus and draws a pattern on a substrate mounted on the moving member.

9. A manufacturing method for manufacturing a product comprising:
drawing a pattern latent image on a substrate having a photosensitive agent applied thereonto using the charged particle beam drawing system according to claim 8;
developing the substrate having the pattern latent image drawn thereon; and
processing the developed substrate to produce the product having a pattern thereon.
